(19) United States
(12) Patent Application Publication
(10) Pub. No.: US 2023/0178683 A1
(43) Pub. Date: Jun. 8, 2023

(54) DISPLAY PANEL AND MANUFACTURING METHOD THEREOF

(71) Applicant: TCL CHINA STAR OPTOELECTRONICS TECHNOLOGY CO., LTD., Shenzhen, Guangdong (CN)

(72) Inventor: Xingwu CHEN, Shenzhen, Guangdong (CN)

(21) Appl. No.: 17/622,827

(22) PCT Filed: Dec. 12, 2021
(86) PCT No.: PCT/CN2021/140177

§ 371 Date: Dec. 26, 2021

(30) Foreign Application Priority Data
Dec. 8, 2021 (CN) 202111490556.X

(51) Int. Cl. H01L 33/10; H01L 27/15; H01L 33/00; H01L 33/50

(52) U.S. Cl. CPC H01L 33/10; H01L 27/156; H01L 33/005; H01L 33/505

(57) ABSTRACT

A display panel and a manufacturing method thereof are disclosed. The display panel includes a first base plate. The first base plate includes a first substrate, a plurality of light-emitting components, and a reflective part. The light-emitting components are disposed on a side of the first substrate. The reflective part is disposed between two adjacent light-emitting components and includes a plurality of cholesteric liquid crystals.

### FIELD

The present disclosure relates to a field of display technologies, and more particularly, to a display panel and a manufacturing method thereof.

### BACKGROUND

With rapid development display technologies, liquid crystal displays (LCDs) have become a mainstream display. In addition, direct display products, such as micro light-emitting diodes (micro LEDs) and mini light-emitting diodes (mini LEDs) which are collectively referred to as MLEDs below, are also gradually becoming popular.

Compared with LCDs, MLEDs have advantages such as high contrast and high brightness. However, in MLED displays, light-emitting chips horizontally emit light, causing severe crosstalk between different sub-pixels having different colors. Generally, to reduce crosstalk, a black adhesive or a white adhesive is coated on two sides of the MLED chips. However, the white adhesive absorbs light poorly, so that it cannot solve a crosstalk issue. The black adhesive can absorb light, but it will reduce a utilization ratio of light.

### SUMMARY

To solve the above issue, the present disclosure provides a display panel and a manufacturing method thereof, which can not only effectively reduce crosstalk but also increase a utilization ratio of light.

The present disclosure provides a display panel, comprising a first base plate, wherein the first base plate comprises:
a first substrate;
a plurality of light-emitting components disposed on a side of the first substrate; and
a reflective part disposed between two adjacent light-emitting components, wherein the reflective part comprises a plurality of cholesteric liquid crystals.

In one embodiment, the reflective part comprises a polymer matrix and a plurality of liquid crystal microcapsules (LCMs) dispersed in the polymer matrix, and the cholesteric liquid crystals are disposed in the LCMs.

In one embodiment, the cholesteric liquid crystals are planar cholesteric liquid crystals.

In one embodiment, a reflective wavelength of the cholesteric liquid crystals ranges from 380 nm to 780 nm.

In one embodiment, the light-emitting components are a plurality of blue-light-emitting components, and a reflective wavelength of the cholesteric liquid crystals ranges from 400 nm to 500 nm.

In one embodiment, the display panel comprises a display area and a non-display area, the non-display area is defined on at least one side of the display area, the light-emitting components are disposed in the display area, and the reflective part is disposed in the non-display area.

In one embodiment, the light-emitting components comprise a first light-emitting component and a second light-emitting component, a color of light emitted from the first light-emitting component and a color of light emitted from the second light-emitting component are different, a first reflective part is disposed between the first light-emitting component and the second light-emitting component, the first reflective part comprises a first cholesteric liquid crystal and a second cholesteric liquid crystal, the first cholesteric liquid crystal is configured to reflect light emitted from the first light-emitting component, and the second cholesteric liquid crystal is configured to reflect light emitted from the second light-emitting component.

In one embodiment, the light-emitting components comprise a third light-emitting component, the color of light emitted from the first light-emitting component, the color of light emitted from the second light-emitting component, and a color of light emitted from the third light-emitting component are different, a second reflective part is disposed between the second light-emitting component and the third light-emitting component, the second reflective part comprises the second cholesteric liquid crystal and a third cholesteric liquid crystal, the second cholesteric liquid crystal is configured to reflect light emitted from the second light-emitting component, and the third cholesteric liquid crystal is configured to reflect light emitted from the third light-emitting component.

In one embodiment, the light-emitting components comprise a first light-emitting component, a second light-emitting component, and a third light-emitting component, a color of light emitted from the first light-emitting component, a color of light emitted from the second light-emitting component, and a color of light emitted from the third light-emitting component are different, the reflective part comprises a first cholesteric liquid crystal, a second cholesteric liquid crystal, and a third cholesteric liquid crystal, the first cholesteric liquid crystal is configured to reflect light emitted from the first light-emitting component, the second cholesteric liquid crystal is configured to reflect light emitted from the second light-emitting component, and the third cholesteric liquid crystal is configured to reflect light emitted from the third light-emitting component.

In one embodiment, the display panel comprises a second base plate, wherein the second base plate is disposed opposite to the first base plate; and

wherein the second base plate comprises a second substrate and a color filter layer, the color filter layer is disposed on a side of the second substrate close to the first base plate, the color filter layer comprises a first color filter part, a second color filter part, and a third color filter part, the first color filter part comprises a first color film block and a first color conversion block, the first color film block is disposed on a side of the second base plate close to the first base plate, the first color conversion block is disposed on a side of the first color film block close to the first base plate, the second color filter part comprises a second color film block and a second color conversion block, the second color film block is disposed on a side of the first base plate, the third color filter part comprises a third color film block and a light-transmitting block, the third color film block is disposed on a side of the second base plate close to the first base plate, and the light-transmitting block is disposed on a side of the third color film block close to the first base plate.

In one embodiment, light-emitting components are mini light-emitting diodes (LEDs) or micro LEDs.

In one embodiment, the polymer matrix is selected from one or more of polymethyl methacrylate, polyethylene terephthalate, polystyrene, polyethylene, polyvinyl chloride, polyamide, and polycarbonate.

In one embodiment, the LCMs are circular or elliptical.

The present disclosure provides a method of manufacturing a display panel, wherein the display panel comprises a first base plate, and the method comprises following steps:
providing a first substrate;
forming a plurality of light-emitting components on a side of the first substrate; and
forming a reflective part between two adjacent light-emitting components to obtain the first base plate, wherein the reflective part comprises a plurality of cholesteric liquid crystals.

In one embodiment, the step of forming the reflective part, comprising the cholesteric liquid crystals, between two adjacent light-emitting components comprises following steps:
mixing a plurality of nematic liquid crystals, a liquid crystal ultraviolet (UV) polymerizable monomer, a chiral compound, and a UV light initiator with each other to obtain a reflective liquid crystal material;
manufacturing a plurality of liquid crystal microcapsules (LCMs) from the reflective liquid crystal material;
mixing the LCMs, a photoinitiator, a dispersant, and a solvent with each other to obtain a reflective photoresist material; and
coating the reflective photoresist material between two adjacent light-emitting components, and curing the reflective photoresist material to obtain the reflective part.

In one embodiment, the reflective liquid crystal material comprises following substances: 60 wt% to 98% nematic liquid crystals, 0 wt% to 30 wt% liquid crystal UV polymerizable monomer, 0.05 wt% to 11% chiral compound, and 0.05 wt% to 2.5 wt% UV light initiator.

In one embodiment, the LCMs are manufactured from the liquid crystal material by an emulsion method or a microfluidic method.

In one embodiment, the step of manufacturing the LCMs from the reflective liquid crystal material comprises following steps:

distributing the reflective liquid crystal material in 10 wt% polyvinyl alcohol solution, stirring the solution to prepare liquid crystal emulsion in water, and performing a polymerization process, a filtration process, and a washing process or a plurality of liquid crystal microspheres.

Regarding the beneficial effects:

In the present disclosure, a reflective part is disposed between adjacent light-emitting components. The reflective part comprises a plurality of reflective cholesteric liquid crystals which can emit light emitted from the light-emitting components. Therefore, crosstalk can be effectively reduced, and a utilization ratio of light can be increased.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic top view showing a display panel according to a first embodiment of the present disclosure.

FIG. 2 is a cross-sectional view showing the display panel of FIG. 1 taken along line A-A.

FIG. 3 is a schematic diagram showing reflectivity of cholesteric liquid crystals used in the first embodiment of the present disclosure under different wavelengths.

FIG. 4 is a schematic top view showing a display panel according to a second embodiment of the present disclosure.

FIG. 5 is a cross-sectional view showing the display panel of FIG. 4 taken along line A-A.

FIG. 6 is a schematic top view showing a display panel according to a third embodiment of the present disclosure.

FIG. 7 is a cross-sectional view showing the display panel of FIG. 6 taken along line A-A.

FIG. 8 is a schematic top view showing a display panel according to a fourth embodiment of the present disclosure.

FIG. 9 is a cross-sectional view showing the display panel of FIG. 8 taken along line A-A.

FIG. 10 is a flowchart showing a method of manufacturing a display panel provided by the present disclosure.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature. In addition, terms such as “first” and “second” are used herein for purposes of description and are not intended to indicate or imply relative importance or significance. Thus, features limited by “first” and “second” are intended to indicate or imply including one or more than one these features.

The present disclosure provides a display panel and a manufacturing method thereof. The display panel provided by the embodiment can be used in cell phones, tablets, electronic readers, electronic display screens, notebooks, cell phones, augmented reality (AR) devices, virtual reality (VR) devices, media players, wearable devices, digital cameras, or car navigators.

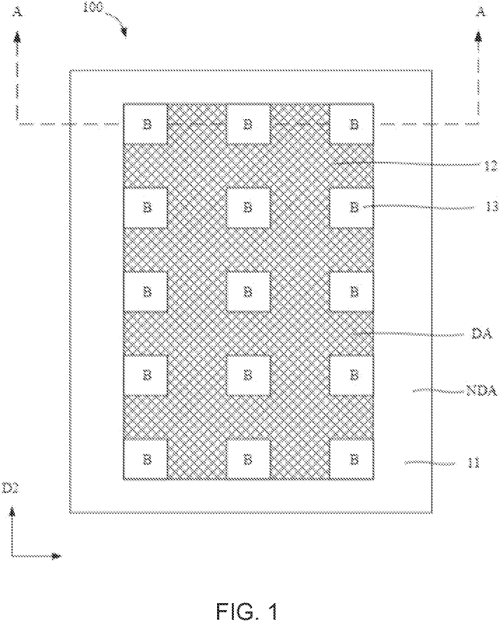

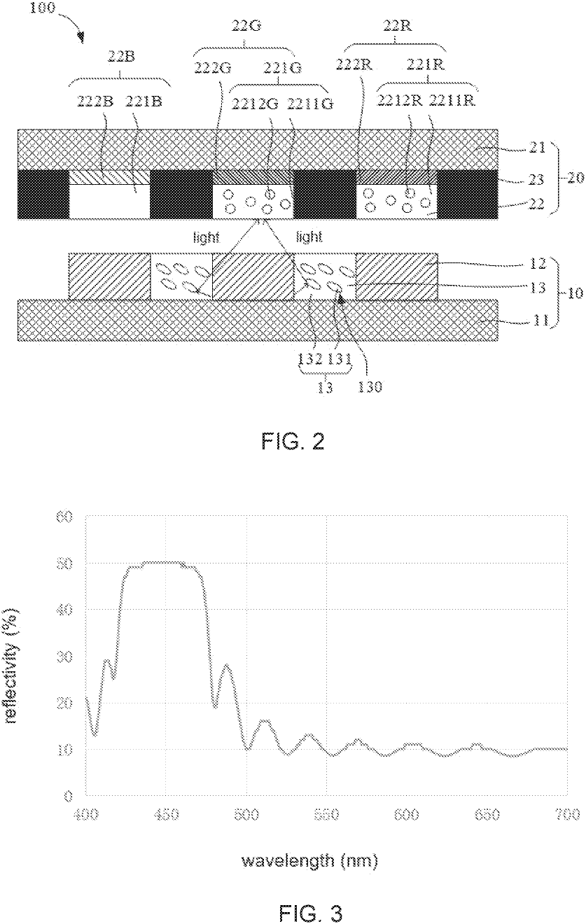

The display panel provided by the present disclosure may be a micro light-emitting diode (micro LED) display panel or a mini light-emitting diode (mini LED) display panel. Please refer to FIG. 1 and FIG. 2, a display panel 100 includes a first base plate 10 and a second base plate 20. The first base plate 10 and the second base plate 20 are disposed opposite to each other. The first base plate 10 is a light-emitting substrate, and the second base plate 20 is a color filter substrate 20.

The first base plate 10 includes a first substrate 11, a plurality of light-emitting components 12 disposed on the first substrate 11, and a reflective part 13 disposed between two adjacent light-emitting components 12.

The first substrate 11 may be a glass substrate, a plastic substrate, or a flexible substrate.

A plurality of light-emitting components 12 may be arranged on the first substrate 11 in a matrix manner. The light-emitting components 12 may be micro LED chips or mini-LED chips. Optionally, the light-emitting components 12 may be light-emitting chips having same or different colors. Preferably, all of the light-emitting components 12 are blue light-emitting chips.

The reflective part 13 is used to reflect light emitted from the light-emitting components 12 to prevent crosstalk between light emitted from two adjacent light-emitting components 12. Furthermore, the display panel 100 includes a display area DA and a non-display area NDA, and the non-display area NDA is defined on at least one side of the display area DA. In a specific embodiment, the non-display area NDA is defined around the display area DA. The light-emitting components 12 are disposed in the display area DA, and the reflective part 13 may be disposed in the display area DA. In other embodiments, the reflective part 13 may also be simultaneously disposed in the display area DA and the non-display area NDA. It should be noted that, in the present disclosure, a matrix area around the light-emitting components 12 is defined as the non-display area NDA. A matrix formed from the light-emitting components 12 and an area between the light-emitting components 12 are defined as the display area DA. An area occupied by the reflective part 13 as shown in FIG. 1 is the display area DA of the disclosure.

The reflective part 13 includes a plurality of cholesteric liquid crystals 131. The cholesteric liquid crystals 131 are soft photonic crystals with a periodic supercoil structure, which can selectively reflect light having different wavelengths to produce structural colors. The cholesteric liquid crystals 131 can be formed by doping a light-responsive chiral molecule into nematic liquid crystals. Stimulated by an external light source, a structure of the light-response chiral molecules is changed, which induces the periodic supercoil structure to be changed. Therefore, a reflective wavelength of the cholesteric liquid crystals 131 can be adjusted. The reflective wavelength λ of the cholesteric liquid crystal 131 satisfies the Bragg’s formula of crystal diffraction:

λ=2npsinφ

In the formula, λ is a wavelength of reflected light, n is an average refractivity, p is a pitch of the cholesteric liquid crystals 131, and φ is an angle between incident light and a surface of the liquid crystals. The pitch P is a distance between a director at one layer pointing a direction and the director at another layer pointing the same direction after being rotated 360° along a coil direction.

The cholesteric liquid crystals 131 have a planar state and a focal conic state. Both the cholesteric liquid crystals 131 in the planar state and the cholesteric liquid crystals 131 in the focal conic state can reflect light. The cholesteric liquid crystals 131 in the planar state have a better reflective effect. In the present embodiment, it is preferable that the cholesteric liquid crystals 131 are planar cholesteric liquid crystals 131. Because selective reflection phenomenon in the planar state is very sensitive to the pitch of the liquid crystals, the pitch of the cholesteric liquid crystals 131 can be changed by adjusting a temperature or an electric field. Therefore, reflective devices having cholesteric liquid crystals 131 can emit light with different colors.

Optionally, control an alignment direction of the cholesteric liquid crystals 131, the cholesteric liquid crystal 131 may be dispersed in a polymer matrix 132 to form the liquid crystal microcapsule 130. The reflective part 13 includes the polymer matrix 132 and the liquid crystal microcapsules 130 dispersed in the polymer matrix 132. Specifically, the polymer matrix 132 may be selected one or more of polymethyl methacrylate (PMMA), polyethylene terephthalate (PET), polystyrene (PS), polyethylene (PE), polyvinyl chloride (PVC), polyamide (PA), and polycarbonate (PC). The cholesteric liquid crystals 131 are disposed in the liquid crystal microcapsule 130. The liquid crystal microcapsule 130 can be circular or elliptical and can reflect light in different directions. A step of aligning the cholesteric liquid crystals 131 can be omitted. In addition, liquid crystals which are evenly aligned have higher light transmittance. Therefore, After the liquid crystals, which are evenly aligned, are made into the liquid crystal microcapsule 130, the light transmittance is negligible because of reflection and scattering of the liquid crystal microcapsule 130.

It should be understood that, in the present disclosure, an alignment layer configured to control an alignment direction of the cholesteric liquid crystals 131 may also be formed on the first substrate 11. The alignment layer is disposed at a position where the reflective part 13 needs to be formed, such as an area between adjacent light-emitting components 12. Then, the cholesteric liquid crystals 131 is disposed on the alignment layer to form the reflective part 13 having the cholesteric liquid crystals 131.

Optionally, a reflective wavelength of the cholesteric liquid crystals 131 ranges from 380 nm to 780 nm. That is, the cholesteric liquid crystals 131 can reflect all visible light. Because the light-emitting components 12 of the present embodiment are blue light-emitting components 12, the reflective part 13 can reflect light reflected by the light-emitting components 12. Preferably, because the light-emitting components 12 of the present embodiment are blue light-emitting components 12, the reflective wavelength of the cholesteric liquid crystals 131 may range from 400 nm to 500 nm. That is, the cholesteric liquid crystals 131 can reflect blue light. Please refer to FIG. 3, a schematic diagram showing reflectivity of the cholesteric liquid crystals 131 of the first embodiment of the present disclosure under different wavelengths is provided. An abscissa denotes a wavelength of incident light, and a unit is nm. An ordinate denotes reflectivity, and a unit is %.

The second base plate 20 includes a second substrate 21 and a color filter layer 22 disposed on the second substrate 21. The color filter layer 22 includes a first color filter part 22G, a second color filter part 22R, and a third color filter part 22B. The first color filter part 22G, the second color filter part 22R, and the third color filter part 22B are sequentially arranged along a first direction D1 and are spaced apart from each other. A light-shielding layer 23 configured to prevent crosstalk is further disposed between adjacent color filters. Each light-shielding layer 23 corresponds to one reflective part 13. The reflective part 13 may produce structural colors due to reflected wavelengths. Therefore, by disposing the light-shielding layer 23 on a light-emitting side of the reflective part 13, not only can crosstalk between adjacent sub-pixels be prevented, but also the structural colors of the reflective part 13 can be blocked. Each color filter part corresponds to one light-emitting component 12. Specifically, the first color filter part 22G is a green color filter part, the second color filter 22R is a red color filter, and the third color filter 22B is a blue color filter. Specifically, the first color filter part 22G includes a first color filter block 222G and a first color conversion block 221 G. The first color filter block 222G is disposed on a side of the second base plate 20 close to the first base plate 10, and the first color conversion block 221G is disposed on a side of the first color filter block 222G close to the first base plate 10. The first color film block 222G is a green color film block. The first color conversion block 221G includes a first transparent matrix 2211G and a plurality of green quantum dots 2212G dispersed in the first transparent matrix 2211G. The second color filter part 22R includes a second color filter block 222R and a second color conversion block 221R. The second color filter block 222R is disposed on a side of the second base plate 20 close to the first base plate 10, and the second color conversion block 221R is disposed on a side of the second color filter block 222R close to the side of the first base plate 10. The second color film block 222R is a red color film block. The second color conversion block 221R includes a second transparent matrix 2211R and a plurality of red quantum dots 2212R dispersed in the second transparent matrix 2211R. The third color filter part 22B includes a third color filter block 222B and a second transparent substrate 2211R. The third color filter block 222B is disposed on a side of the second base plate 20 close to the first base plate 10, and the third transparent substrate 221B is disposed on a side of the third color film block 222B close to the first base plate 10. The third color film block 222B is a blue color film block. Quantum dots may not be added to the third transparent matrix 221B. The first color filter 22G and the second color filter 22R may also be referred to as a QDCF film. It should be understood that color conversion particles in the color conversion blocks may also be other materials, such as phosphors.

When the display panel 100 works, the blue light-emitting components 12 emit blue light, and the blue light emitted by the light-emitting components 12 corresponding to the first color filter part 22G can be converted into green light by the green quantum dots 2212G in the first color conversion block 221G. Then, the green light is emitted after passing through the color film block. The blue light emitted by the light-emitting components 12 corresponding to the second color filter part 22R can be converted into red light by the red quantum dots 2212R in the second color conversion block 221R. The red light is emitted after passing through the color film block. The blue light emitted by the light-emitting components 12 corresponding to the third color filter part 22B passes through the third transparent matrix 221B and then is emitted. When the light-emitting components 12 corresponding to the first color filter part 22G are turned on, the light-emitting components 12 corresponding to the second color filter part 22R and the light-emitting components 12 corresponding to the third color filter part 22B are also turned on. Similarly, light emitted from the light-emitting components 12 corresponding to the second color filter portion 22R and the third color filter portion 22B is reflected to the color filter portions respectively corresponding thereto, thereby preventing crosstalk between adjacent sub-pixels. When the light-emitting components 12 corresponding to the first color filter portion 22G are turned on, and the light-emitting component 12 corresponding to the second color filter portion 22R and the third color filter portion 22B are turned off, blue light emitted by the light-emitting components 12 corresponding to the first color filter part 22G and the second color filter part 22R is not only emitted in a vertical direction, but is also emitted in an oblique direction and a lateral direction. The vertical direction here refers to a direction perpendicular to the first substrate 11. The oblique direction is a direction intersecting but not perpendicular to the vertical direction. The lateral direction refers to a direction parallel to the first substrate 11. Because the reflective part 13 is disposed between two adjacent light-emitting components 12, obliquely-emitted light and laterally-emitted light of the blue light emitted from the light-emitting components 12 corresponding to the first color filter part 22G is reflected into the reflective part 13, and is reflected by the cholesteric liquid crystals 131 in the reflective part 13 to the first filter part 22G corresponding to the light-emitting components 12. Therefore, the blue light is prevented from being emitted into the second color filter part 22R and the third color filter part 22B, and a light leakage issue will not occur on the second color filter part 22R and the third color filter part 22B.

Conventional white adhesives do not absorb light, especially blue light. In the present embodiment, the cholesteric liquid crystals which can selectively reflect blue light are provided, thereby increasing reflectivity of light and reducing crosstalk and light leakage between adjacent sub-pixels. Light reflected by the reflective part can finally enter the corresponding color filter part, thereby improving a utilization rate of light.

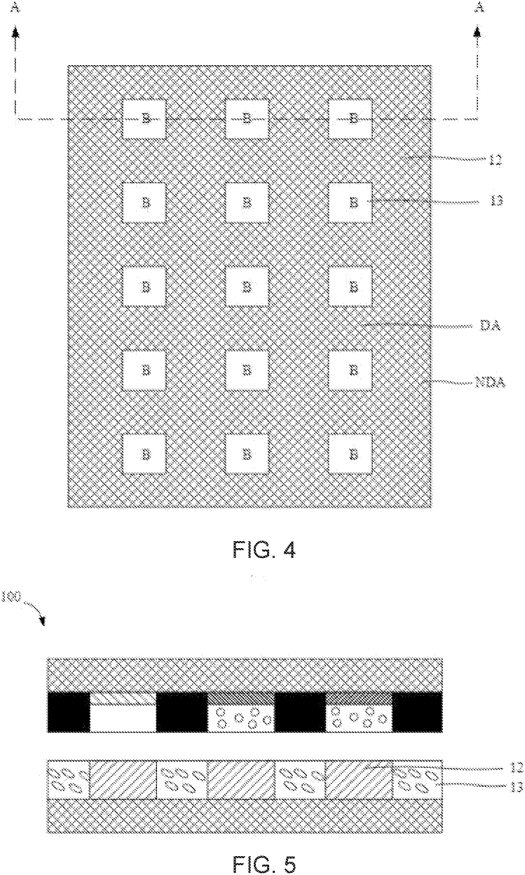

Please refer to FIG. 4 and FIG. 5, in a display panel 100 provided by a second embodiment of the present disclosure, the reflective part 13 is further disposed in the non-display area NDA. By disposing the reflection part 13 having the cholesteric liquid crystals 131 in the non-display area NDA surrounding the display area, light emitted from the light-emitting components 12 to the non-display area NDA can be reflected into the display area, thereby improving light-emitting efficiency.

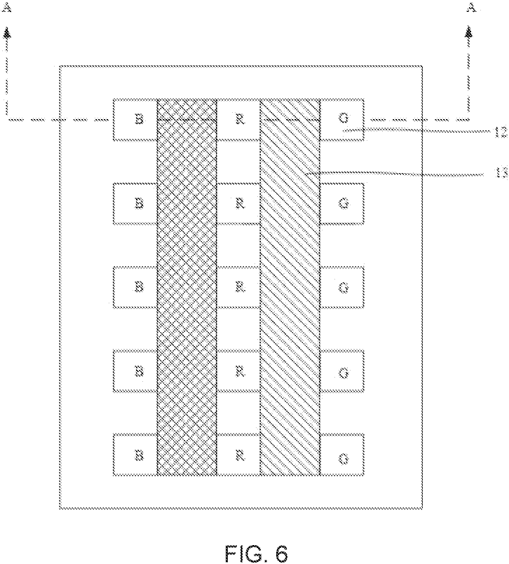

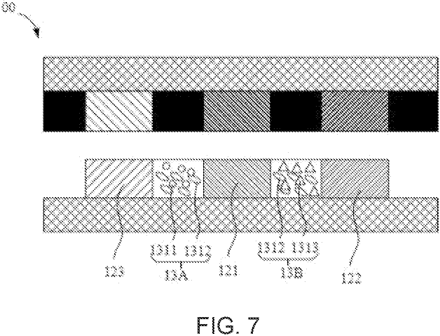

Please refer to FIG. 6 and FIG. 7, in a display panel 100 provided by a third embodiment of the present disclosure, the light-emitting components 12 may also be light-emitting chips having different colors. Preferably, the light-emitting components 12 include blue light-emitting chips, green light-emitting chips, and red light-emitting chips. Alternatively, the light-emitting components 12 include the blue light-emitting chip, the green light-emitting chips, the red light-emitting chips, and light-emitting chips having a fourth color. The light-emitting chips of the fourth color may be white light-emitting chips or yellow light-emitting chips. According to different light-emitting chips, the reflective part 13 of the present disclosure can be correspondingly provided.

Specifically, the light-emitting components 12 include a first light-emitting component 121, a second light-emitting component 122, and a third light-emitting component 123. A color of light emitted from the first light-emitting component 121, a color of light emitted from the second light-emitting component 122, and a color of light emitted from the third light-emitting component 123 are different. A first reflective part 13A is disposed between the first light-emitting component 121 and the second light-emitting component 122. The first reflective part 13A includes a first cholesteric liquid crystal 1311 and a second cholesteric liquid crystal 1312. The first cholesteric liquid crystal 1311 is configured to reflect light emitted from the first light-emitting component 121. The second cholesteric liquid crystal 1312 is configured to reflect light emitted from the second light-emitting component 122. A second reflective portion 13B is disposed between the second light-emitting component 122 and the third light-emitting component 123. The second reflective part 13B includes the second cholesteric liquid crystal 1312 and a third cholesteric liquid crystal 1313. The second cholesteric liquid crystal 1312 is configured to reflect light emitted from the second light-emitting component 122. The third cholesteric liquid crystal 1313 is configured to reflect light emitted from the third light-emitting component 123. It should be understood that the first cholesteric liquid crystal 1311, the second cholesteric liquid crystal 1312, and the third cholesteric liquid crystal 1313 are disposed in the reflective portion 13 in a form of the liquid crystal microcapsules 130. As shown in the figure, the first cholesteric liquid crystal 1311, the second cholesteric liquid crystal 1312, and the third cholesteric liquid crystal 1313 can be made into different liquid crystal microcapsules 130, or can be disposed in same liquid crystal microcapsule 130 in pairs.

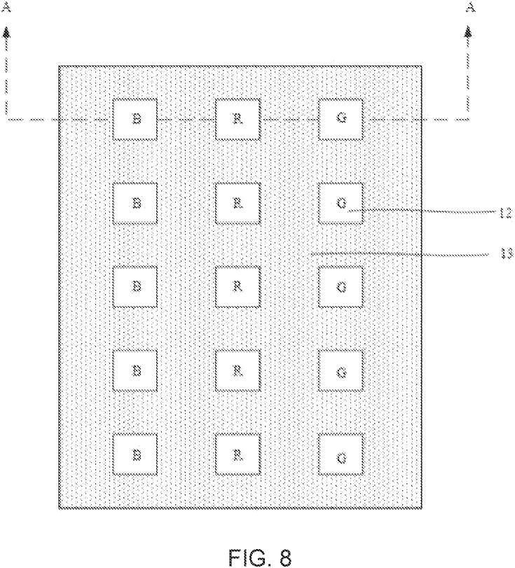

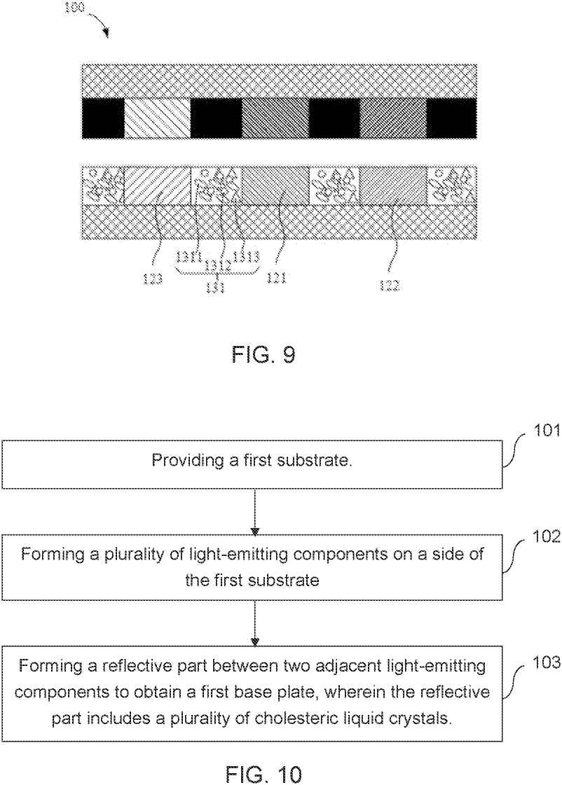

Please refer to FIG. 8 and FIG. 9, in a display panel 100 of a fourth embodiment of the present disclosure, the light-emitting components 12 include the first light-emitting component 121, the second light-emitting component 122, and the third light-emitting component 123. A color of light emitted from the first light-emitting component 121, a color of light emitted from the second light-emitting component 122, and a color of light emitted from the third light-emitting component 123 are different. The reflective part 13 includes the first cholesteric liquid crystal 1311, the second cholesteric liquid crystal 1312, and the third cholesteric liquid crystal 1313. The first cholesteric liquid crystal 1311 is configured to reflect light emitted from the first light-emitting component 121. The second cholesteric liquid crystal 1312 is configured to reflect light emitted from the second light-emitting component 122. The third cholesteric liquid crystal 1313 is configured to reflect light emitted from the third light-emitting component 123. As shown in the figure, the first cholesteric liquid crystal 1311, the second cholesteric liquid crystal 1312, and the third cholesteric liquid crystal 1313 can be disposed in a same liquid crystal microcapsule 130, or can be made into different liquid crystal microcapsules 130. The first cholesteric liquid crystal 1311, the second cholesteric liquid crystal 1312, and the third cholesteric liquid crystal 1313 can be made into different liquid crystal microcapsules 130, or can be disposed in a same liquid crystal microcapsule 130.

Please refer to FIG. 10, the present disclosure further provides a method of manufacturing a display panel. The display panel includes a first base plate. The method of manufacturing the display panel includes following steps:

101: providing a first substrate.

The first substrate may be a glass substrate, a plastic substrate, or a flexible substrate.

102: forming a plurality of light-emitting components on a side of the first substrate, wherein the light-emitting components may be arranged on the first substrate in an array manner. The light-emitting components may be micro-LED chips or mini-LED chips. Optionally, the light-emitting components may be light-emitting chips with a same color or with different colors. Preferably, the light-emitting components may be blue light-emitting chips.

103: forming a reflective part between two adjacent light-emitting components to obtain the first base plate, wherein the reflective part includes a plurality of cholesteric liquid crystals.

The reflective part may be formed between two adjacent light-emitting components by spin coating, embossing, or printing. The reflective part is configured to reflect light emitted from the light-emitting components, thereby preventing crosstalk between light emitted between two adjacent light-emitting components. Furthermore, the display panel includes a display area and a non-display area. The non-display area is defined on at least one side of the display area. In a specific embodiment, the non-display area is defined around the display area. The light-emitting components are arranged in the display area, and the reflective part may be disposed in the display area. Also, the reflective part can be simultaneously disposed in the display area and the non-display area.

Specifically, the step 103 may include following steps:

1031: mixing a plurality of nematic liquid crystals, a liquid crystal ultraviolet (UV) polymerizable monomer, a chiral compound, and a UV photoinitiator with each other to obtain a reflective liquid crystal material.

In a specific embodiment, a proportion of each substance in the reflective liquid crystal material is: 60 wt% to 98 wt% nematic liquid crystals, 0 wt% to 30 wt% liquid crystal UV polymerizable monomer, 0.05 wt% to 11 wt % chiral compound, and 0.05 wt% to 2.5 wt% UV photoinitiator. The above materials are mixed, heated, and stirred to obtain the reflective liquid crystal material. Selective reflection band of the cholesteric liquid crystal is blue. As shown in FIG. 3, because of this ratio, the cholesteric liquid crystals with a reflective wavelength range of blue light can be obtained. Nematic liquid crystal molecules are aligned in a single direction and will not be rotated. Therefore, the chiral compounds are added to induce the liquid crystal molecules to be rotated, thereby converting the nematic liquid crystals into the cholesteric liquid crystals. The chiral compounds are compounds with an asymmetric center. An amount of the liquid crystal UV polymerizable monomer can be 0 wt%, and the liquid crystal microcapsules can be formed by intermolecular force or hydrophobicity. To improve stability of the liquid crystal microcapsules, a liquid crystal UV polymerizable monomer can be added. The cholesteric liquid crystals have a planar state and a focal conic state. Both the cholesteric liquid crystals in the planar state and the cholesteric liquid crystals in the focal conic state can reflect light. A cholesteric reflection effect in the planar state is better. In the present embodiment, it is preferable that the cholesteric liquid crystals are planar cholesteric liquid crystals. A reflective wavelength of the cholesteric liquid crystals may range from 400 nm to 500 nm. Optionally, when all of the light-emitting components of the display panel are blue light-emitting components, the reflection wavelength of the cholesteric liquid crystals ranges from 380 nm to 780.

1032: forming the liquid crystal microcapsules from reflective liquid crystal material.

In the step 1032, the liquid crystal microcapsules can be formed by an emulsion method, a microfluidic method, or other methods. Taking the emulsion method as an example, a mixed reflective liquid crystal material is dispersed into a 10 wt% polyvinyl alcohol (PVA) solution. Liquid crystal emulsion in water is formed by magnetic stirring. Then liquid crystal microcapsules are formed by UV polymerization, filtration, and cleaning.

To control an alignment direction of the cholesteric liquid crystals, the cholesteric liquid crystal can be dispersed in a polymer matrix to form the liquid crystal microcapsules during the step 1031 and the step 1032. The liquid crystal microcapsules can be circular or elliptical and can reflect light in different directions. The liquid crystals do not need to be aligned. In addition, liquid crystals, which are evenly aligned, have higher light transmittance. Under reflection and scattering of the liquid crystal microcapsules, light transmittance is negligible after the liquid crystal microcapsules formed, the light transmittance is negligible. It should be understood that if the liquid crystal microcapsules are not provided, an alignment layer configured to control an alignment direction of the cholesteric liquid crystals can be formed on the first substrate of the present disclosure. The alignment layer is disposed on an area where the reflective part needs to be formed such as an area between the light-emitting components. Then, the liquid crystals are disposed on the alignment layer to form the reflective part having the cholesteric liquid crystals.

It should be understood that a type of the cholesteric liquid crystals in the reflective part may be one or more according to a color of the light-emitting components. The cholesteric liquid crystals are used to reflect light emitted from the light-emitting components.

1033: mixing the liquid crystal microcapsules, a polymerizable monomer, a photoinitiator, a dispersant, and a solvent with each other to obtain the reflective photoresist material.

In the step 1033, the polymerizable monomer can be selected from one or more of polymethyl methacrylate (PMMA), polyethylene terephthalate (PET), polystyrene (PS), polyethylene (PE), polychloride ethylene (PVC), polyamide (PA), or polycarbonate (PC).

1034: coating the reflective photoresist material between two adjacent light-emitting components, and curing the reflective photoresist material to obtain the reflective part.

The reflective part includes the polymer matrix and the liquid crystal microcapsules dispersed in the polymer matrix. The cholesteric liquid crystals are disposed in the liquid crystal microcapsules. A polymer monomer is polymerized to form the polymer matrix in the step 1033. The polymer matrix is selected from one or more of PMMA, PET, PS, PE, PVC, PA, or PC.

In addition, after the step 103, steps of forming a second base plate 20 and aligning the first base plate 10 with the second base plate 20 to form the display panel may also be conducted. A structure of the second base plate 20 can be referred to the above-mentioned embodiment, and is not described here.

Hereinafter, a method of manufacturing a display panel of an embodiment of the present disclosure is described.

Please refer to FIG. 1 and FIG. 2, the method of the display panel according to the first embodiment of the present disclosure includes the following steps:

2101: providing a first substrate 11.

2102: forming a plurality of light-emitting components 12 on a side of the first substrate 11.

In the present embodiment, all of the light-emitting components 12 are blue light-emitting components 12.

203: forming a reflective part 13 between two adjacent light-emitting components 12 to obtain the first base plate 10, wherein the reflective part 13 includes a plurality of cholesteric liquid crystals 131.

In the present embodiment, the reflective part 13 is disposed only in a display area DA. A reflective wavelength of the cholesteric liquid crystals may range from 400 nm to 500 nm. That is, the cholesteric liquid crystals 131 can reflect blue light. For example, cholesteric liquid crystals have a reflective wavelength range as shown in FIG. 3.

Specifically, the step 203 includes:

2031: mixing a plurality of nematic liquid crystals, a liquid crystalline UV polymerizable monomer, a chiral compound, and a UV light initiator with each other to obtain a reflective liquid crystal material.

2032: manufacturing a plurality of liquid crystal microcapsules from the reflective liquid crystal material.

2033: mixing the liquid crystal microcapsules, a polymerizable monomer, a photoinitiator, a dispersant, and a solvent with each other to obtain the reflective photoresist material.

2034: coating the reflective photoresist material between two adjacent light-emitting components 12, and curing the reflective photoresist material to obtain the reflective part 13.

Please refer to FIG. 4 and FIG. 5, a difference between a method of manufacturing a display panel according to the second embodiment of the present disclosure the method of manufacturing the display panel according to the first embodiment is: in the present embodiment, the reflective part 13 is also disposed in the non-display area NDA.

Please refer to FIG. 6 and FIG. 7, a difference between a method of manufacturing s display panel according to the third embodiment of the present disclosure and the method of manufacturing the display panel according to the first embodiment is:

in the present embodiment, in the step 2102, the light-emitting components 12 are light-emitting chips having different colors. Preferably, the light-emitting components 12 include blue light-emitting chips, green light-emitting chips, and red light-emitting chips. Alternatively, the light-emitting components 12 include blue light-emitting chips, green light-emitting chips, red light-emitting chips, and light-emitting chips having a fourth color. The light-emitting chips having the fourth color may be white light-emitting chips or yellow light-emitting chips. The reflective part 13 of the present disclosure can be correspondingly provided according to different light-emitting chips.

Specifically, the light-emitting components 12 include a first light-emitting component 121, a second light-emitting component 122, and a third light-emitting component 123. A color of light emitted from the first light-emitting component 121, a color of light emitted from the second light-emitting component 122, and a color of light emitted from the third light-emitting component 123 are different.

In the step 203, a first reflective part 13A is formed between the first light-emitting component 121 and the second light-emitting component 122. The first reflective part 13A includes a first cholesteric liquid crystal 1311 and a second cholesteric liquid crystal 1312. The first cholesteric liquid crystal 1311 is configured to reflect light emitted from the first light-emitting component 121. The second cholesteric liquid crystal 1312 is configured to reflect light emitted from the second light-emitting component 122. A second reflective portion 13B is formed between the second light-emitting component 122 and the third light-emitting component 123. The second reflective portion 13B includes a second cholesteric liquid crystal 1312 and a third cholesteric liquid crystal 1313. The second cholesteric liquid crystal 1312 is configured to reflect light emitted from the second light-emitting component 122. The third cholesteric liquid crystal 1313 is configured to reflect light emitted from the third light-emitting component 123. It should be understood that the first cholesteric liquid crystal 1311, the second cholesteric liquid crystal 1312, and the third cholesteric liquid crystal 1313 are disposed in the reflective part 13 in a form of the liquid crystal microcapsules.

Please refer to FIG. 8 and FIG. 9, a difference between a method of manufacturing a display panel of the fourth embodiment of the present disclosure and the method of manufacturing the display panel of the first embodiment is:

In the step 2102, the light-emitting components 12 include a first light-emitting component 121, a second light-emitting component 122, and a third light-emitting component 123. A color of light emitted from the first light-emitting component 121, a color of light emitted from the second light-emitting component 122, and a color of light emitted from the third light-emitting component 123 are different.

In step 203, the reflective part 13 includes a first cholesteric liquid crystal 1311, a second cholesteric liquid crystal 1312, and a third cholesteric liquid crystal 1313. The first cholesteric liquid crystal 1311 is configured to reflect light emitted from the first light-emitting component 121. The second cholesteric liquid crystal 1312 is configured to reflect light emitted from the second light-emitting component 122. The third cholesteric liquid crystal 1313 is configured to reflect light emitted from the third light-emitting component 123. The first cholesteric liquid crystal 1311, the second cholesteric liquid crystal 1312, and the third cholesteric liquid crystal 1313 are disposed in the reflective part 13 in a form of the liquid crystal microcapsules. The first cholesteric liquid crystal 1311, the second cholesteric liquid crystal 1312, and the third cholesteric liquid crystal 1313 can be made into different liquid crystal microcapsules, or can be disposed in a same liquid crystal microcapsule.

Furthermore, for those skilled the art, specific embodiments and applications may be modified according to the spirit of the present disclosure. In summary, the contents of the specification shall not be construed as causing limitations to the present disclosure.

1. A display panel, comprising a first base plate, wherein the first base plate comprises:
a first substrate;
a plurality of light-emitting components disposed on a side of the first substrate; and
a reflective part disposed between two adjacent light-emitting components, wherein the reflective part comprises a plurality of cholesteric liquid crystals.

2. The display panel of claim 1, wherein the reflective part comprises a polymer matrix and a plurality of liquid crystal microcapsules (LCMs) dispersed in the polymer matrix, and the cholesteric liquid crystals are disposed in the LCMs.

3. The display panel of claim 1, wherein the cholesteric liquid crystals are a plurality of planar cholesteric liquid crystals.

4. The display panel of claim 1, wherein a reflective wavelength of the cholesteric liquid crystals ranges from 380 nm to 780 nm.

5. The display panel of claim 1, wherein the light-emitting components are a plurality of blue-light-emitting components, and a reflective wavelength of the cholesteric liquid crystals ranges from 400 nm to 500 nm.

6. The display panel of claim 1, wherein the display panel comprises a display area and a non-display area, the non-display area is defined on at least one side of the display area, the light-emitting components are disposed in the display area, and the reflective part is disposed in the non-display area.

7. The display panel of claim 1, wherein the light-emitting components comprise a first light-emitting component and a second light-emitting component, a color of light emitted from the first light-emitting component and a color of light emitted from the second light-emitting component are different, a first reflective part is disposed between the first light-emitting component and the second light-emitting component, the first reflective part comprises a first cholesteric liquid crystal and a second cholesteric liquid crystal, the first cholesteric liquid crystal is configured to reflect light emitted from the first light-emitting component, and the second cholesteric liquid crystal is configured to reflect light emitted from the second light-emitting component.

8. The display panel of claim 7, wherein the light-emitting components comprise a third light-emitting component, the color of light emitted from the first light-emitting component, the color of light emitted from the second light-emitting component, and a color of light emitted from the third light-emitting component are different, a second reflective part is disposed between the second light-emitting component and the third light-emitting component, the second reflective part comprises the second cholesteric liquid crystal and a third cholesteric liquid crystal, the second cholesteric liquid crystal is configured to reflect light emitted from the second light-emitting component, and the third cholesteric liquid crystal is configured to reflect light emitted from the third light-emitting component.

9. The display panel of claim 1, wherein the light-emitting components comprise a first light-emitting component, a second light-emitting component, and a third light-emitting component, a color of light emitted from the first light-emitting component, a color of light emitted from the second light-emitting component, and a color of light emitted from the third light-emitting component are different, the reflective part comprises a first cholesteric liquid crystal, a second cholesteric liquid crystal, and a third cholesteric liquid crystal, the first cholesteric liquid crystal is configured to reflect light emitted from the first light-emitting component, the second cholesteric liquid crystal is configured to reflect light emitted from the second light-emitting component, and the third cholesteric liquid crystal is configured to reflect light emitted from the third light-emitting component.

10. The display panel of claim 1, wherein display panel comprises a second base plate, wherein the second base plate is disposed opposite to the first base plate; and
wherein the second base plate comprises a second substrate and a color filter layer, the color filter layer is disposed on a side of the second substrate close to the first base plate, the color filter layer comprises a first color filter part, a second color filter part, and a third color filter part, the first color filter part comprises a first color film block and a first color conversion block, the first color film block is disposed on a side of the second base plate close to the first base plate, the first color conversion block is disposed on a side of the first color film block close to the first base plate, the second color filter part comprises a second color film block and a second color conversion block, the second color film block is disposed on a side of the first base plate, the third color filter part comprises a third color film block and a light-transmitting block, the third color film block is disposed on a side of the second base plate close to the first base plate, and the light-transmitting block is disposed on a side of the third color film block close to the first base plate.

11. The display panel of claim 1, wherein light-emitting components are mini light-emitting diodes (LEDs) or micro LEDs.

12. The display panel of claim 1, wherein the polymer matrix is selected from one or more of polymethyl methacrylate, polyethylene terephthalate, polystyrene, polyethylene, polyvinyl chloride, polyamide, and polycarbonate.

13. The display panel of claim 1, wherein the LCMs are circular or elliptical.

14. A method of manufacturing a display panel, wherein the display panel comprises a first base plate, and the method comprises following steps:
providing a first substrate;
forming a plurality of light-emitting components on a side of the first substrate; and
forming a reflective part between two adjacent light-emitting components to obtain the first base plate, wherein the reflective part comprises a plurality of cholesteric liquid crystals.

15. The method of claim 14, wherein the step of forming the reflective part, comprising the cholesteric liquid crystals, between two adjacent light-emitting components comprises following steps:
mixing a plurality of nematic liquid crystals, a liquid crystal ultraviolet (UV) polymerizable monomer, a chiral compound, and a UV light initiator with each other to obtain a reflective liquid crystal material;
manufacturing a plurality of liquid crystal microcapsules (LCMs) from the reflective liquid crystal material;
mixing the LCMs, a photoinitiator, a dispersant, and a solvent with each other to obtain a reflective photoresist material; and
coating the reflective photoresist material between two adjacent light-emitting components, and curing the reflective photoresist material to obtain the reflective part.

16. The method of claim 15, wherein the reflective liquid crystal material comprises following substances: 60 wt% to 98% nematic liquid crystals, 0 wt% to 30 wt% liquid crystal UV polymerizable monomer, 0.05 wt% to 11% chiral compound, and 0.05 wt% to 2.5 wt% UV light initiator.

17. The method of claim 15, wherein the LCMs are manufactured from the liquid crystal material by an emulsion method or a microfluidic method.

18. The method of claim 15, wherein the step of manufacturing the LCMs from the reflective liquid crystal material comprises following steps:
distributing the reflective liquid crystal material in 10 wt% polyvinyl alcohol solution, stirring the solution to prepare liquid crystal emulsion in water, and performing a polymerization process, a filtration process, and a washing process.
